(19) United States
(12) Patent Application Publication
(10) Pub. No.: US 2005/0035932 A1
(43) Pub. Date: Feb. 17, 2005

(54) Electroluminescent display device and manufacturing method of the same

(75) Inventors: Ryuji Nishikawa, Gifu (JP); Kiyoshi Yoneda, Gifu (JP)

Correspondence Address: MORRISON & FOERSTER LLP, 1650 TYSONS BOULEVARD, SUITE 300, MCLEAN, VA, 22102, US

(73) Assignee: Sanyo Electric Co., Ltd., Moriguchi-shi (JP)

(21) Appl. No.: 10/874,760

(22) Filed: Jun. 24, 2004

(30) Foreign Application Priority Data
Jun. 30, 2003 (JP) 2003-186115

(51) Int. Cl. G09G 3/30

(52) U.S. Cl. 345/76

(57) ABSTRACT

This invention provides an organic EL display device automatically correcting light emission intensity of a display portion in accordance with intensity of external light, in which the number of components is reduced and sensitivity in detection of an external light sensor is improved. An organic EL element of top emission type, a driving TFT for driving the organic EL element, which is formed of a TFT of top gate type, and an external light sensor formed of a TFT of bottom gate type are integrally formed on a same glass substrate. Since the external light sensor is formed of a TFT of bottom gate type, external light is not blocked by a gate electrode, thereby improving sensitivity in detection of the external light.

### CROSS-REFERENCE OF THE INVENTION

This invention is based on Japanese Patent Application No. 2003-186115, the content of which is incorporated by reference in its entirety.

### BACKGROUND OF THE INVENTION

1. Field of the Invention

This invention relates to an electroluminescent display device, particularly having a function of automatically correcting light emission intensity of a display portion in accordance with external light intensity (brightness).

2. Description of the Related Art

In recent years, an organic electroluminescent (hereafter, referred to as EL) display device using EL elements is receiving attention as a display device substituting for a CRT or an LCD. Particularly, an organic EL display device having thin film transistors (hereafter, referred to as TFTs) as switching elements for driving the organic EL elements has been developed.

The organic EL display device is applied to display panels used for cellular phones and personal digital assistants, for example. The organic EL display device, which can automatically correct light emission intensity of a display portion in accordance with intensity (brightness) of external light entering from outside of the display portion, has been also developed.

Such technologies are disclosed in the Japanese Patent Application Publication Nos. 2002-175029 and 2002-297096.

In the organic EL display device automatically correcting light emission intensity of the display portion in accordance with external light intensity, however, the display portion and an external light sensor detecting external light intensity are independently formed. This increases the number of components forming the organic EL display device, and makes a manufacturing procedure complex.

### SUMMARY OF THE INVENTION

This invention provides an organic EL display device where a display portion and an external light sensor are integrally formed on the same substrate.

In the organic EL display device of the invention, an organic EL element, a driving transistor for driving the organic EL element, and an external light sensor are integrally formed on the same glass substrate. The organic EL element is formed of an organic EL element of top emission type, the driving transistor is formed of a thin film transistor of top gate type, and the external light sensor is formed of a thin film transistor of bottom gate type.

Furthermore, in an organic EL display device of the invention, the organic EL element is formed of an organic EL element of bottom emission type, the driving transistor is formed of a thin film transistor of top gate type, and the external light sensor is formed of a thin film transistor of top gate type, being integrally formed on a same glass substrate.

According to an aspect of this invention, the organic EL display device which automatically corrects the light emission intensity of the display portion in accordance with the external light intensity can be realized by integrally forming the organic EL element, the driving transistor, and the external light sensor on the same substrate. This can reduce the number of the components for the display device and simplify the manufacturing process. Furthermore, the external light sensor formed of a TFT is disposed with an active layer in a position where a gate electrode does not block the external light so that sensitivity in detection of the external light improves.

### BRIEF DESCRIPTION OF THE DRAWINGS

FIG. 1 is a schematic circuit diagram of an organic EL display device of a first embodiment of the invention.

FIG. 2 shows a relationship between external light intensity and EL light emission intensity in the organic EL display device of FIG. 1.

FIG. 3 is a schematic cross-sectional view of an organic EL element and its periphery, and an external light sensor of the first embodiment of the invention.

FIG. 4 is a schematic cross-sectional view of an organic EL element and its periphery, and an external light sensor of a second embodiment of the invention.

FIG. 5 is a circuit diagram showing a structure of a sensor circuit of the first and second embodiments of the invention.

FIG. 6 is an operational timing chart of the sensor circuit of FIG. 5.

### DETAILED DESCRIPTION OF THE INVENTION

A structure of an organic EL display device of an embodiment of the invention will be described with reference to drawings.

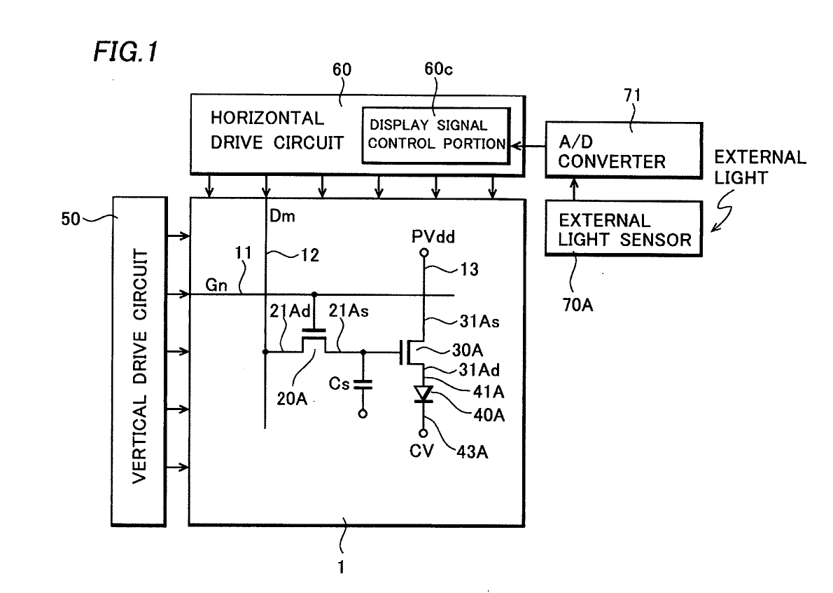

FIG. 1 is a schematic circuit diagram of an organic EL display device of a first embodiment of the invention. In this embodiment, a plurality of pixels is disposed in a matrix in a display portion 1. FIG. 1 shows only one pixel.

A gate signal line 11 supplying a gate signal Gn for selecting a pixel and a drain signal line 12 supplying a display signal Dm to the pixel are formed crossing each other in each of pixels. A pixel selecting TFT (thin film transistor) 20A, an organic EL element 40A (e.g. organic EL element of top emission type) serving as a self-emissive element, and a driving TFT (e.g. TFT of top gate type) 30A for supplying an electric current to the organic EL element 40A are disposed in a region enclosed with these signal lines.

A gate of the pixel selecting TFT 20A is connected with the gate signal line 11 so as to be supplied with a gate signal Gn. A drain 21Ad of the pixel selecting TFT 20A is connected with the drain signal line 12 so as to be supplied with a display signal Dm. A source 21As of the pixel selecting TFT 20A is connected with a gate of the driving TFT 30A. A source 31As of the driving TFT 30A is supplied with positive power supply voltage PVdd from a power supply line 13. A drain 31Ad of the driving TFT 30A is connected with an anode 41A of the organic EL element 40A. A cathode 43A of the organic EL element 40A is supplied with power supply voltage CV.

The gate signal Gn is outputted from a vertical drive circuit 50 disposed on a periphery of the display portion 1. The display signal Dm is outputted from a horizontal drive circuit 60 disposed on a periphery of the display portion 1. The gate of the driving TFT 30A is connected with a storage capacitor Cs. The storage capacitor Cs is provided to store the display signal Dm to be applied to the pixel for a field period by storing electric charge corresponding to the display signal Dm.

An external light sensor 70A (e.g. bottom gate type) detecting external light intensity (brightness) is provided in a position where external light entering the display portion 1 can be detected. The external light sensor 70A generates a predetermined current or voltage when receiving external light and electrically detects this, thereby detecting the external light intensity. An output terminal of the external light sensor 70A is connected with an input terminal of an A/D converter 71, and an output terminal of the A/D converter 71 is connected with an input terminal of the horizontal drive circuit 60. The horizontal drive circuit 60 is provided with a display signal control portion 60c. The display signal control portion 60c has a function of changing amplitude of the display signal Dm in accordance with a digital signal (external light intensity) inputted from the A/D converter.

Next, an operation of the above-described organic EL display device will be described. When the gate signal Gn becomes high level for one horizontal period, the pixel selecting TFT 20A turns on. Then, the display signal Dm is applied from the drain signal line 12 to the gate of the driving TFT 30A through the pixel selecting TFT 20A.

The conductance of the driving TFT 30A changes in accordance with the display signal Dm supplied to the gate thereof, and a drive current in accordance with the conductance is supplied to the organic EL element 40A through the driving TFT 30A, thereby lighting the organic EL element 40A. When the driving TFT 30A turns off in accordance with the display signal Dm supplied to the gate, a drive current does not flow in the driving TFT 30A, thereby turning off the light of the organic EL element 40A.

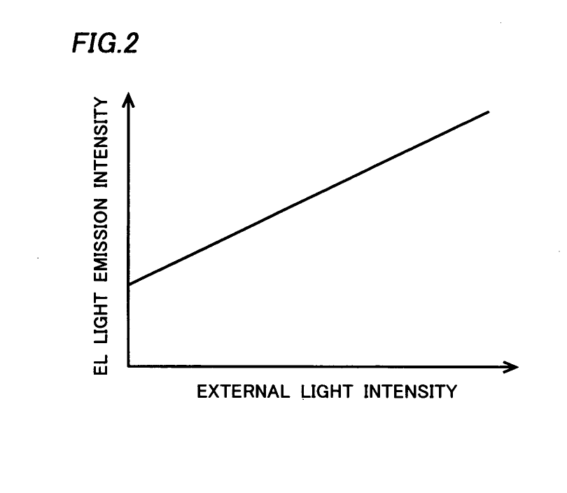

In the above-described organic EL display device, light emission intensity of the organic EL element 40A (hereafter, referred to as EL light emission intensity) provided in each of the pixels of the display portion 1 increases or decreases in accordance with intensity of external light entering from outside of the display portion 1. A chart of FIG. 2 shows a relationship between the external light intensity and the EL light emission intensity. That is, the more the external light intensity increases, the more the EL light emission intensity increases at a predetermined rate.

Correction of EL light emission intensity in accordance with external light intensity shown in FIG. 2 is performed as described below. The external light sensor 70A detects external light entering from outside of the display portion 1, and outputs an analog signal (voltage or current) indicating external light intensity to the A/D converter 71. The A/D converter 71 converts the analog signal entering from the external light sensor 70A into a digital signal, and outputs the digital signal indicating the external light intensity to the display signal control portion 60c provided in the horizontal drive circuit 60.

This display signal control portion 60c changes an amplitude value of the display signal Dm in accordance with each of sample values of the digital signal indicating the external light intensity, and outputs it. That is, the display signal Dm outputted by the horizontal drive circuit 60 has amplitude corresponding to the external light intensity. Therefore, when the pixel selecting TFT 20 is in an on state, the conductance of the driving TFT 30A increases or decreases in accordance with the amplitude of the display signal Dm applied to the gate of the driving TFT 30A. This increases or decreases a drive current to be supplied to the organic EL element 40A, thereby completing the correction of the EL light emission intensity of the organic EL element 40A in accordance with the external light intensity.

Next, structures of the organic EL element 40A, the driving TFT 30A, and the external light sensor 70A will be described in detail.

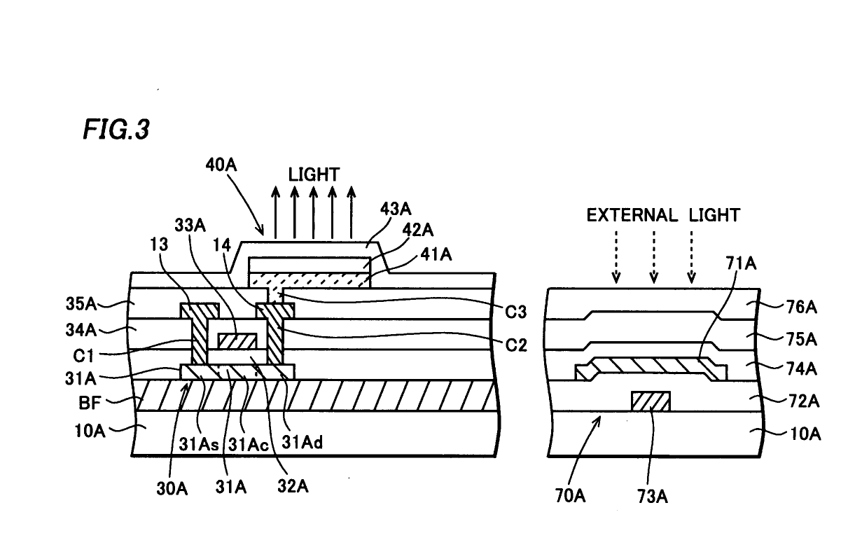

FIG. 3 is a schematic cross-sectional view of the organic EL element 40A and its periphery, and the external light sensor 70A of FIG. 1. The organic EL element 40A is formed of an organic EL element of top emission type, the driving TFT 30A for driving the organic EL element 40A is formed of a TFT of top gate type, and the external light sensor 70A is formed of a TFT of bottom gate type. The organic EL element 40A, the driving TFT 30A, and the external light sensor 70A are formed on a same glass substrate 10A. Hereafter, the structures of these elements will be described.

A buffer layer BF formed by laminating SiNx and SiO₂ in this order, an active layer 31A formed by poly-crystallizing an a-Si film by laser beam irradiation, a gate insulating film 32A formed by laminating an SiO₂ film and an SiNx film in this order, and a gate electrode 33A formed of a metal having a high melting point such as Cr (chromium) or Mo (molybdenum) are formed on the glass substrate 10A in this order. The active layer 31A is provided with a channel 31Ac, a source 31As, and a drain 31Ad, the source 31As and the drain 31Ad being disposed on both sides of the channel 31Ac, respectively.

An interlayer insulating film 34A formed by laminating an SiO₂ film, an SiNₓ film and an SiO₂ film in this order is formed on whole surfaces of the gate insulating film 32 and the gate electrode 33A. A contact hole C1 is provided in the interlayer insulating film 34A in a position corresponding to the source 31As, and a power supply line 13 supplied with positive power supply voltage PVdd is provided by filling the contact hole C1 with metal such as Al (aluminum). A contact hole C2 is provided in the interlayer insulting film 34A in a position corresponding to the drain 31Ad, and a drain electrode 14 is provided by filling the contact hole C2 with a metal such as Al. Furthermore, a planarization insulating film 35A for planarizing a surface, which is made of, for example, organic resin, is formed on the whole surface.

A contact hole C3 is provided in the planarization insulating film 35A in a position corresponding to the drain electrode 14, and a metal such as Al fills the contact hole C3, so that the drain electrode 14 and the anode 41A of the organic EL element 40A are in contact with each other. The anode 41A is an electrode having characteristics of reflecting light without transmission. This anode 41A is made of metal such as Al, and can have a single-layered structure made of metal having a high light reflection rate or have a multi-layered structure made of ITO and a metal.

The organic EL element 40A is formed in each of the pixels, being isolated as an island. The organic EL element 40A is formed by laminating the anode 41A, an emissive layer 42A, and a transparent cathode 43A transmitting light emitted by the emissive layer 42A, in this order. The emissive layer 42A is formed by laminating, for example, a hole transport layer, an emissive layer, and an electron transport layer (not shown). The transparent cathode 43A is supplied with power supply voltage CV (not shown).

In this organic EL element 40A, holes injected from the anode 41A and electrons injected from the transparent cathode 43A are recombined in the emissive layer 42A. The recombined holes and electrons activate organic molecules forming the emissive layer 42A to generate excitons. Then, light is emitted from the emissive layer 42A in a process of radiation of the excitons and released outside from the transparent cathode 43A.

Furthermore, on the glass substrate 10A formed with the driving TFT 30A and the organic EL element 40A, the external light sensor 70A is disposed in a position where external light from outside of the display portion 1 can be received. The external light sensor 70A is formed of a TFT of bottom gate type.

That is, a gate electrode 73A made of a metal having a high melting point such as Cr or Mo, a gate insulating film 72A also serving as a buffer layer BF, an active layer 71A formed by poly-crystallizing an a-Si film by laser beam irradiation, insulating films 74A and 75A, and a planarization insulating film 76A are formed on the glass substrate 10A in this order. External light enters the active layer 71A from an exposed surface on the same side as the side of the transparent cathode 43A serving as an emitting surface. The external light sensor 70A electrically detects external light received by the active layer 71A, and outputs an electric current or voltage corresponding to the intensity of the external light. In the structure of this external light sensor 70A, the gate electrode 73A blocking external light does not exist between the surface where external light enters and the active layer 71A due to its bottom gate structure.

Therefore, an area of the active layer 71A receiving external light increases and thus sensitivity in detection of external light improves than a case where the external light sensor 70A is made of a TFT of top gate type (not shown) (laminated with a glass substrate, an active layer, a gate insulating film and a gate electrode in this order). The external light sensor 70A uses the TFT of bottom gate type as a photodiode, for example, thereby outputting a photocurrent corresponding to the external light.

As described above, in this embodiment, the organic EL element of top emission type 40A, the driving TFT 30A formed of a TFT of top gate type and the external light sensor 70A formed of a TFT of bottom gate type are integrally formed on the same glass substrate 10A. This reduces the number of elements and simplifies a manufacturing procedure. For example, a manufacturing method as described below can be employed. The gate electrode 73A is formed on the glass substrate 10A, and the buffer layer BF also serving as the gate insulating film 72A is formed so as to cover the gate electrode 73A.

The active layers 31A and 71A are formed on the buffer layer BF serving as the gate insulating film 72A, and the gate insulating film 32A also serving as the insulating film 74A is formed thereon. Furthermore, the gate electrode 33A is formed thereon, and the interlayer insulating film 34A also serving as the insulating film 75A is formed so as to cover the gate electrode 33A. Then, the power supply line 13 and the drain electrode 14 are formed, and the planarization insulating films 35A and 76A are formed so as to cover these. The anode 41A is formed on the planarization insulating film 35A, and the emissive layer 42A and the transparent cathode 43A are formed, being laminated on the anode 41A.

Since the external light sensor 70A is formed of a TFT of bottom gate type, the external light reaches the active layer 71A without being blocked by the gate electrode 73A. This improves sensitivity in detecting the external light intensity.

Although not shown, the pixel selecting TFT 20A is formed of a TFT of top gate type, as is the case with the driving TFT 30A. Generally, compared to the TFT of bottom gate type, the TFT of top gate type can prevents currents from flowing in excess by activation of carriers in the active layer 31A with EL light emission, and has a higher carrier mobility. Therefore, the TFT of top gate type is suitable for the driving TFT 30A, and particularly for the pixel selecting TFT 20A. On the other hand, the external light sensor 70A utilizes a dark current flowing in the TFT, and thus does not need to have high carrier mobility.

Note that even the TFT of bottom gate type can also be applied to both the pixel selecting TFT 20A and the driving TFT 30A.

Next, a second embodiment of the invention will be described. In the first embodiment, the organic EL element of top emission type, the driving TFT of top gate type, and the external light sensor formed of the TFT of bottom gate type are integrally formed on the same substrate. In the second embodiment, however, an organic EL element of bottom emission type, a driving TFT of top gate TFT, and an external light sensor of a TFT of top gate type are integrally formed on the same substrate. This embodiment will be described below with reference to drawings in detail. The organic EL element 40A of FIG. 1 is replaced by an organic EL element of bottom emission type 40B, and the external light sensor 70A is replaced by an external light sensor 70B formed of a TFT of top gate type. A schematic circuit diagram of this embodiment is the same as that of FIG. 1.

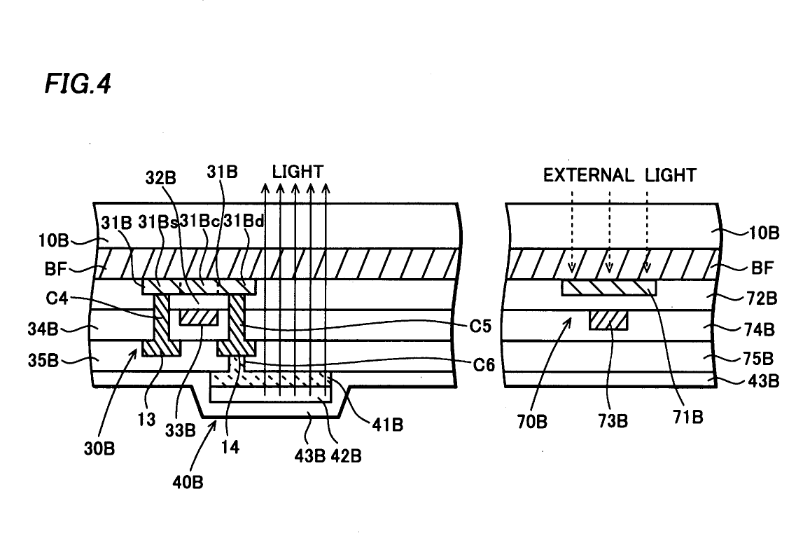

FIG. 4 is a schematic cross-sectional view of the organic EL element 40B and its periphery, and the external light sensor 70B in this embodiment. As shown in FIG. 4, in the embodiment using the organic EL element 40B of bottom emission type, light emitted by the organic EL element 40B is emitted from an exposed surface of a transparent glass substrate 10B, different from the first embodiment. Furthermore, on a surface on an opposite side of the exposed surface of the transparent glass substrate 10B, the driving TFT 30B of top gate type is formed.

That is, the buffer layer BF formed by laminating, for example, SiNx and SiO₂ in this order, an active layer 31B formed by poly-crystallizing an a-Si film by laser beam irradiation, a gate insulating film 32B and a gate electrode 33B made of a metal having a high melting point such as Cr or Mo and disposed in a position corresponding to the active layer 31B are formed on the transparent glass substrate 10B in this order. The active layer 31B is formed with a channel 31Bc, a source 31Bs, and a drain 31Bd, the source 31Bs and the drain 31Bd being disposed on both sides of the channel 31Bc, respectively.

An interlayer insulating film 34B formed by laminating an SiO₂ film, an SiNₓ film and an SiO₂ film in this order is formed on whole surfaces of the gate insulating film 32B and the gate electrode 33B. A contact hole C4 is provided in the interlayer insulating film 34B in a position corresponding to the source 31Bs, and a power supply line 13 supplied with positive power supply voltage PVdd is provided therein by filling the hole with a metal such as Al. A contact hole C5 is provided in the interlayer insulting film 34B in a position corresponding to the drain 31Bd, and a drain electrode 14 is provided by filling the hole with a metal such as Al.

Furthermore, a planarization insulating film 35B for planarizing a surface, which is made of, for example, organic resin, is formed on the whole surface. A contact hole C6 is provided in the planarization insulating film 35B in a position corresponding to the drain electrode 14, and metal such as Al fills the hole so that the drain electrode 14 and the anode 41B of the organic EL element 40B are in contact with each other. This transparent anode 41B is a transparent electrode made of ITO (indium tin oxide) and so on.

The organic EL element 40B is formed in each of the pixels, being isolated as an island. The organic EL element 40B is formed by laminating the transparent anode 41B, an emissive layer 42B, and a cathode 43B supplied with power supply voltage CV (not shown) (for example, made of Al, or magnesium indium alloy) in this order. Light emitted by the emissive layer 42B is emitted from the transparent glass substrate 10B through the transparent anode 41B.

Furthermore, on the glass substrate 10B formed with the driving TFT 30B and the organic EL element 40B, the external light sensor 70B is disposed in a position where the external light from outside of the display portion 1 can be received. The external light sensor 70B is formed of a TFT of top gate type.

That is, on the transparent glass substrate 10B, the buffer layer BF formed by laminating, for example, SiNx and SiO₂, in this order, an active layer 711B formed by poly-crystallizing an a-Si film by laser beam irradiation, a gate insulating film 72B, a gate electrode 73B made of a metal having a high melting point such as Cr or Mo, an interlayer insulating film 74B, and a planarization insulating film 75B are formed in this order. Furthermore, a cathode 43B of the organic EL element 40B can be formed, extending over the planarization insulating film 75B. In this case, the external light can be blocked from entering a back surface of the external light sensor 70B.

External light enters the active layer 71B from an exposed surface on the same side as the side of the transparent glass substrate 10B serving as an emitting surface. The external light sensor 70B electrically detects external light received by the active layer 71B, and outputs an electric current or voltage corresponding to the intensity of the light source.

In the structure of this external light sensor 70B, a gate electrode 73B blocking external light does not exist between the transparent glass substrate 10B where external light enters and the active layer 71B. This increases an area of the active layer 71B which receives external light, and thus improves sensitivity in detecting the external light than a case where the external light sensor 70B is formed of a TFT of bottom gate type (formed by laminating a transparent glass substrate, a gate electrode, a gate insulating film, and an active layer in this order).

Furthermore, although not shown, the pixel selecting TFT 20A is formed of a TFT of top gate type, as is the case with the driving TFT 30A.

In the above-described embodiment using the organic EL element 40B of bottom emission type, the driving TFT 30B made of a TFT of top gate type and the external light sensor 70B are formed on the same transparent glass substrate 10B so that the number of the elements decreases.

Since the external light sensor 70B is formed of a TFT of top gate type, the external light reaches the active layer 71B without being blocked by the gate electrode 73B. This improves sensitivity in detecting the external light intensity.

Furthermore, the driving TFT 30B and the external light sensor 70B are formed of a TFT of top gate type, these can be formed in a same process. This can simplify a manufacturing process. For example, a manufacturing process described below can be employed.

The buffer layer BF is formed on the glass substrate 10B, and the active layers 31B and 71 are formed on the buffer layer BF. The gate insulating films 32B and 72B are formed on the active layers 31B and 71. Furthermore, the gate electrodes 33B and 73B are formed, and the interlayer insulating films 34B and 74B are formed on the insulating films 32B and 72B so as to cover the gate electrodes 33B and 73B.

Then, the power supply line 13 and the drain electrode 14 are formed thereon, and the planarization insulating films 35B and 75B are formed so as to cover the power supply line 13 and the drain electrode 14. The transparent anode 41B is formed on this planarization insulating film 35B, and the emissive layer 42B and the cathode 43B are formed, being laminated on the transparent anode 41B. Furthermore, the cathode 43B of the organic EL element 40B can be formed extending over the planarization insulating film 75B on the external light sensor 70B, in order to block external light from entering a back surface of the external light sensor 70B.

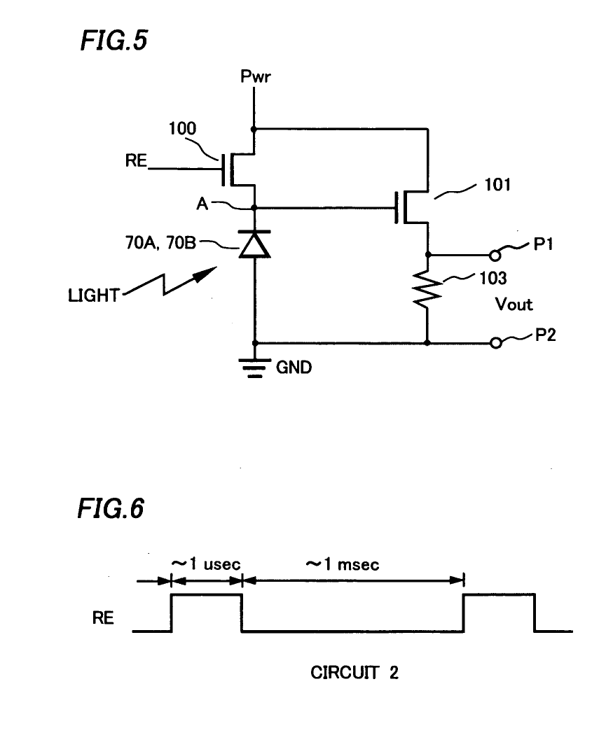

Next, a sensor circuit using the external light sensor 70A or 70B will be described with reference to FIGS. 5 and 6. This sensor circuit is a circuit for converting light received by the external light sensor 70A or 70B into output voltage Vout corresponding thereto. This sensor circuit can be commonly applied to the above first and second embodiments. FIG. 5 is a circuit diagram showing a structure of the sensor circuit, and FIG. 6 is an operational timing chart of this sensor circuit.

In FIG. 5, the external light sensor 70A or 70B having a diode structure and a first resetting TFT 100 are connected in series between electric potential Pwr and ground potential GND (electric potential Pwr>ground potential GND). A second resetting TFT 101 and a resistor 103 are connected in series between the electric potential Pwr and the ground potential GND. These series circuits are connected in parallel. A gate of the first resetting TFT 100 is applied with a resetting signal RE. A gate of the second resetting TFT 101 is supplied with an electric potential of a connection point A between the external sensor 70A or 70B and the resetting TFT 100.

Then, output voltage Vout between terminals P1 and P2, which is outputted from the terminals P1 and P2 at ends of the resistor 103, is taken as external light detection voltage, and inputted in the above-described A/D converter 71.

Note that the first and second resetting TFTs 100 and 101 are of N-channel type in this embodiment, although these TFTs 100 and 101 may be of N-channel type or of P-channel type.

Next, an operation of this circuit will be described with reference to FIG. 6. When the resetting signal RE becomes high level, the first resetting TFT 100 turns on. Accordingly, the gate of the second resetting TFT 101 is applied with electric potential Pwr through the first resetting TFT 100 so that the second resetting TFT 101 also turns on. In this resetting time, the output voltage Vout becomes approximately Pwr (predetermined value) when the impedance of the second resetting TFT 101 is smaller enough than a resistance value of the resistor 103, and does not depend on a photocurrent flowing in the external light sensor 70A or 70B.

Next, when the resetting signal RE becomes low level for the sensing procedure, the first resetting TFT 100 turns off. The connection point A between the external light sensor 70A or 70 and the first resetting TFT 100 becomes in a floating state. However, a leakage at the external light sensor 70A or 70B makes a level of the connection point A close to the ground voltage GND, and thus the potential of the gate of the second resetting TFT 101 reduces, thereby increasing impedance of the second resetting TFT 101. As a result, the output voltage Vout becomes slightly smaller than Pwr.

Then, when the external light sensor 70A or 70B receive light, a photocurrent (a reverse bias current of a diode) corresponding to the light is generated so that electric potential of the external light sensor 70A or 70B (electric potential at the connection point A) reduces. This reduces the potential of the gate of the second resetting TFT 101, thereby increasing the impedance of the second resetting TFT 101. Accordingly, the output voltage Vout reduces.

Therefore, in the above-described operation, the output voltage Vout corresponding to external light intensity can be obtained, and the amplitude of the display signal Dm is controlled by using this output voltage Vout, thereby enabling correction of light emission intensity of the organic EL elements 40A and 40B. Note that in this sensor circuit the external light sensor 70A and 70B are not limited to a diode structure, but other photo sensors can be also applicable.

Although the organic EL elements 40A and 40B are used in the above described first and second embodiments, the invention is not limited to these, but non-organic EL elements can be used instead.

1. An electroluminescent display device comprising:
an electroluminescent element of top emission type disposed on a substrate; and
an external light sensor disposed on the substrate and comprising a thin film transistor of bottom gate type, the external light sensor being configured to be used for correcting light emission intensity of the electroluminescent element.

2. The electroluminescent display device of claim 1, further comprising a driving transistor of top gate type driving the electroluminescent element.

3. The electroluminescent display device of claim 1, further comprising a control portion adjusting an amplitude of a display signal supplied to the electroluminescent element in accordance with an output of the external light sensor.

4. The electroluminescent display device of claim 1, wherein the thin film transistor is configured to operate as a photodiode.

5. The electroluminescent display device of claim 3, further comprising a sensor circuit converting the output of the external light sensor into a voltage and supplying an output of the sensor circuit to the control portion.

6. The electroluminescent display device of claim 5, wherein the sensor circuit includes a first resetting transistor and the external light sensor connected in series between a first electric potential and a second electric potential and includes a second resetting transistor and a resistor connected in series between the first and second electric potentials, the first transistor is configured to receive a resetting signal at a gate thereof, and a gate of the second resetting transistor is connected to a connection point between the first resetting transistor and the external light sensor.

7. The electroluminescent display device of claim 2, wherein the driving transistor comprises a first insulating film disposed on the substrate, a first active layer formed on the first insulating film, a third insulating film disposed on the first insulating film and the first active layer, and a first gate electrode formed on the third insulating film, the external light sensor comprises a second gate electrode formed on the substrate, a second insulating film disposed on the substrate and the second gate electrode, and a second active layer formed on the second insulating film, and the first and second insulating films are each part of a same insulating layer.

8. The electroluminescent display device of claim 7, wherein the external light sensor further comprises a fourth insulating film disposed on the second insulating film and the second active layer, wherein the third and fourth insulating films are each part of another same insulating layer.

9. The electroluminescent display device of claim 7, wherein the first and second active layers are made of a same active layer material.

10. An electroluminescent display device comprising:
an electroluminescent element of bottom emission type disposed on a substrate; and
an external light sensor disposed on the substrate and comprising a thin film transistor of top gate type, the external light sensor being configured to be used for correcting light emission intensity of the electroluminescent element.

11. The electroluminescent display device of claim 10, further comprising a driving transistor of top gate type driving the electroluminescent element.

12. The electroluminescent display device of claim 10, further comprising a control portion adjusting an amplitude of a display signal supplied to the electroluminescent element in accordance with an output of the external light sensor.

13. The electroluminescent display device of claim 10, wherein the thin film transistor is configured to operate as a photodiode.

14. The electroluminescent display device of claim 12, further comprising a sensor circuit converting the output of the external light sensor into a voltage and supplying an output of the sensor circuit to the control portion.

15. The electroluminescent display device of claim 14, wherein the sensor circuit includes a first resetting transistor and the external light sensor connected in series between a first electric potential and a second electric potential and includes a second resetting transistor and a resistor connected in series between the first and second electric potentials, the first transistor is configured to receive a resetting signal at a gate thereof, and a gate of the second resetting transistor is connected to a connection point between the first resetting transistor and the external light sensor.

16. The electroluminescent display device of claim 11, wherein the driving transistor comprises a first active layer formed on the substrate, a first insulating film disposed on the substrate and the first active layer, and a first gate electrode formed on the first insulating film, the external light sensor comprises a second active layer formed on the substrate, a second insulating film disposed on the substrate and the second active layer, and a second gate electrode formed on the second insulating film, and the first and second insulating films are each part of a same insulating film.

17. The electroluminescent display device of claim 16, wherein the first and second active layers are made of a same active layer material.

18. The electroluminescent display device of claim 16, wherein the first and second gate electrodes are made of a same gate electrode material.

19. The electroluminescent display device of claim 10, wherein the electroluminescent element comprises two electrodes and an organic material layer disposed between the two electrodes, and one of the two electrodes that is disposed further from the substrate than another of the two electrodes covers the external light sensor.

20. A method of manufacturing an electroluminescent display device having an electroluminescent element disposed on a substrate, a driving transistor disposed on the substrate and driving the electroluminescent element, and an external light sensor disposed on the substrate and comprising a transistor, the method comprising:
forming a gate electrode of the external light sensor on the substrate;
depositing a first insulating film on the substrate and the gate electrode of the external light sensor;
depositing a layer of an active layer material on the first insulating film;
patterning the deposited layer to form an active layer of the driving transistor and an active layer of the external light sensor;
depositing a second insulating film on the first insulating film, the active layer of the driving transistor and the active layer of the external light sensor; and
forming a gate electrode of the driving transistor on the second insulating film.

21. A method of manufacturing an electroluminescent display device having an electroluminescent element disposed on a substrate, a driving transistor disposed on the substrate and driving the electroluminescent element, and an external light sensor disposed on the substrate and comprising a transistor, the method comprising:
depositing a layer of an active layer material on the substrate;
patterning the deposited layer to form an active layer of the driving transistor and an active layer of the external light sensor;
depositing a first insulating film on the active layer of the driving transistor and the active layer of the external light sensor; and
forming, on the first insulating film, a gate electrode of the driving transistor and a gate electrode of the external light sensor.

22. The method of manufacturing the electroluminescent display device of claim 21, further comprising depositing a second insulating film on the substrate prior to the depositing of the layer of the active layer material.
